(19) United States
(12) Patent Application Publication
(10) Pub. No.: US 2011/0094787 A1
(43) Pub. Date: Apr. 28, 2011

(54) PRINTED CIRCUIT BOARD AND MANUFACTURING METHOD THEREOF

(75) Inventors: YING-TSO LAI, Tu-Cheng (TW); CHUN-JEN CHEN, Tu-Cheng (TW); YU-CHANG PAI, Tu-Cheng (TW); PEI-CHUN LIN, Tu-Cheng (TW); CHIN-HUI CHEN, Tu-Cheng (TW); HSIAO-PING HUANG, Tu-Cheng (TW)

(73) Assignee: HON HAI PRECISION INDUSTRY CO., LTD., Tu-Cheng (TW)

(21) Appl. No.: 12/647,431

(22) Filed: Dec. 25, 2009

(30) Foreign Application Priority Data
Oct. 28, 2009 (CN) 200910308955.2

(51) Int. Cl. H05K 1/11; H05K 3/10

(52) U.S. Cl. 174/262; 29/846

(57) ABSTRACT

A printed circuit board includes a layer. A layer of copper is covered on a surface of the layer. A through hole passes through the printed circuit board. A number of thermal engravings are defined in the layer around the through hole. Each thermal engraving is a groove defined in the surface of the layer, without covered with the layer of copper. The number of thermal engravings are not in contact with each other.

### BACKGROUND

1. Technical Field

The present disclosure relates to a printed circuit board (PCB) and a manufacturing method of the PCB.

2. Description of Related Art

A PCB usually includes a reference layer, which includes copper, and a through hole. A component is mounted on the PCB by inserting a lead through the through hole in the PCB and then soldering the lead in place on an opposite side of the PCB during a reflow process. The lead of the component is electrically connected to the reference layer. The reference layer of the printed circuit board distributes heat quickly due to a large surface area of the copper. However, rapid heat dissipation may lead to defect formation during the soldering process.

### BRIEF DESCRIPTION OF THE DRAWINGS

FIG. 1 is a schematic diagram of an exemplary embodiment of a printed circuit board, the printed circuit board defining a through hole.

FIG. 2 is a sectional view taken along the line II-II of FIG. 1.

FIG. 3 is a graph of temperature in the through hole of a conventional printed circuit board and the printed circuit board in FIG. 1.

FIG. 4 is a flowchart of an exemplary embodiment of a manufacturing method of the printed circuit board in FIG. 1.

### DETAILED DESCRIPTION

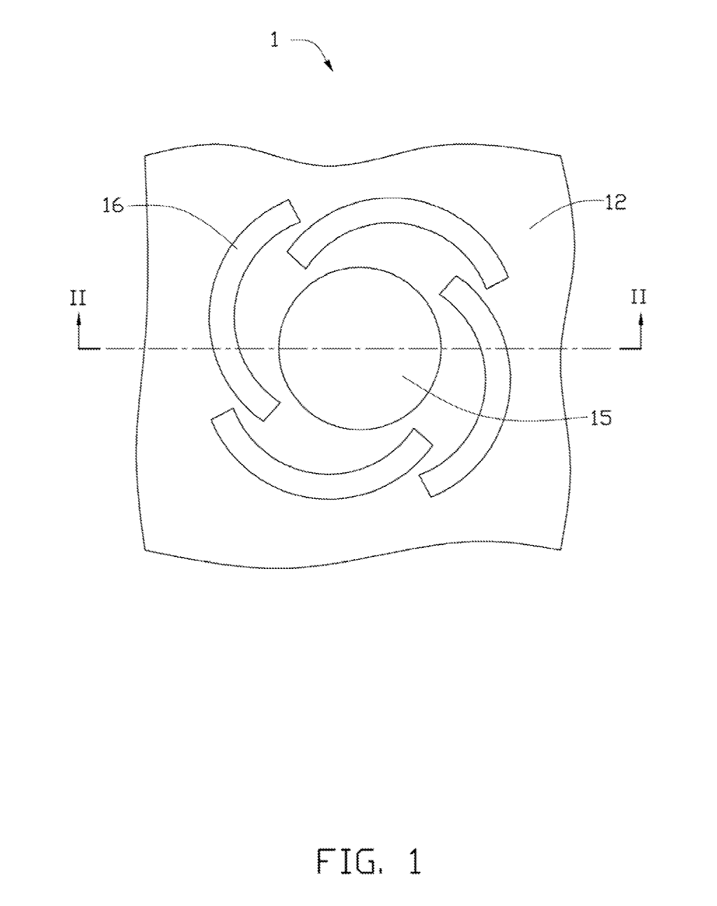

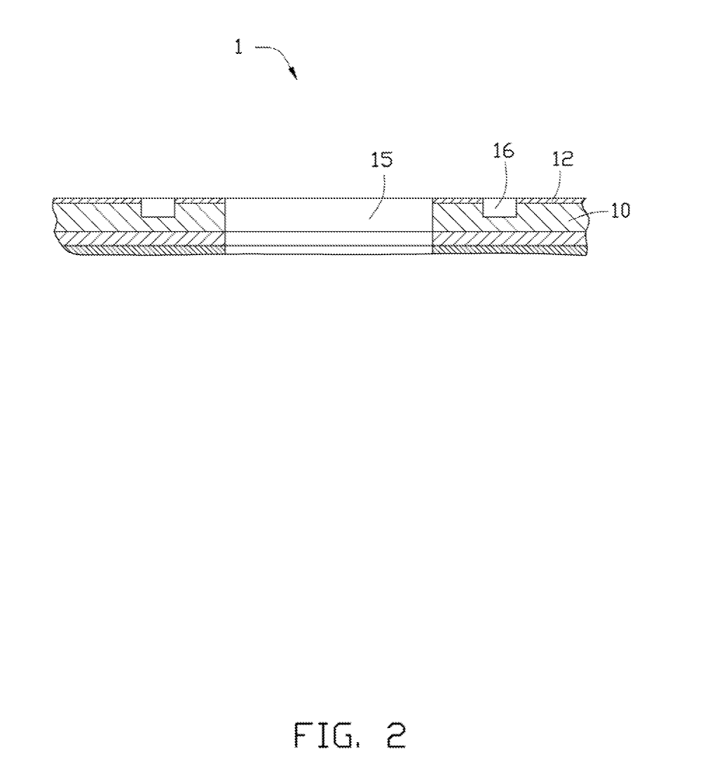

Referring to FIGS. 1 and 2, an exemplary embodiment of a printed circuit board (PCB) 1 includes a ground layer 10 and other layers (not labeled), such as signal layers. The PCB 1 defines a through hole 15 through the ground layer 10 and the other layers. A layer of copper 12 is arranged on a surface of the ground layer 10. The ground layer 10 defines four thermal engravings 16.

A component (not shown) may be mounted on the PCB 1 by inserting a lead of the component through the through hole 15 and then soldering the lead in place on an opposite side of the printed circuit board 1. The lead of the component is electrically connected to the ground layer 10 and other layers, to transmit signals between layers of the PCB 1 and the component.

Each thermal engraving 16 is an arc-shaped groove 16 which is defined in the surface of the ground layer 10. The grooves 16 are not covered by the layer of copper 12. The four grooves 16 are spaced apart from each other and arranged surrounding the through hole 15. Corresponding ends of every two adjacent grooves 16 are juxtaposed. In the embodiment, a depth of each groove 16 is greater than or equal to a thickness of the layer of copper 12.

As a result, when the lead of the component is inserted through the through hole 15, heat dissipation is slower because of relatively less copper in the area of the through hole 15 due to the existence of the thermal engravings 16.

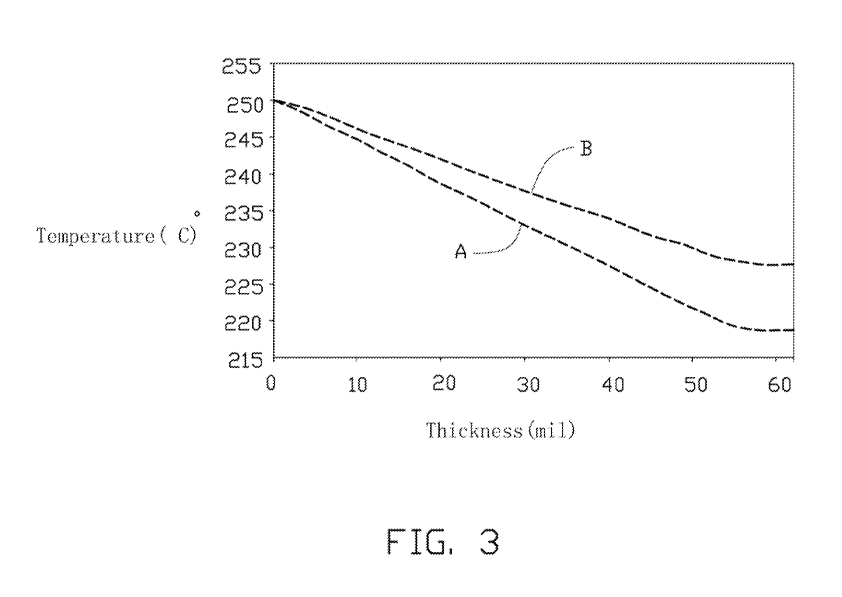

Referring to FIG. 3, a curve A denotes temperatures in a through hole of a conventional PCB, and a curve B denotes temperatures in the through hole 15 of the PCB 1 at various thickness of the ground layer measured during a soldering process. Clearly the temperature in the through hole 15 of the PCB 1 is higher than in the through hole of the conventional PCB during soldering, and the thicker the ground layer the greater the difference in temperature. The higher temperature is indicative of the slower heat dissipation in the area of the through hole 15 during soldering meaning fault formation is decreased or even eliminated.

In other embodiments, the four thermal engravings 16 may be arranged in other layers, such as a power layer of the PCB 1. In addition, the number of the thermal engravings 16 may be changed, such as five or six.

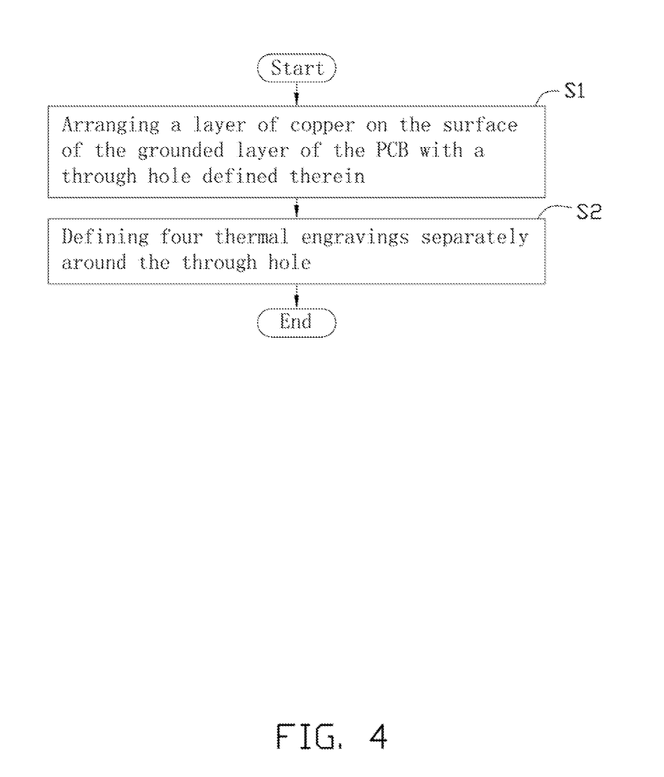

Referring to FIG. 4, a manufacturing method of the PCB 1 includes the following steps.

In step S1, the layer of copper 12 is arranged on the surface of the grounded layer 10 of the PCB 1 with the through hole 15 defined therein.

In step S2, four thermal engravings 16 are separately defined around the through hole 15. The four engravings 16 are not covered by the layer of copper 12 and are not in contact with each other.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising a layer, the layer comprising:
a layer of copper arranged on a surface of the layer;
wherein a through hole passes through the printed circuit board; and
wherein a plurality of thermal engravings is defined in the layer around the through hole, each thermal engraving is a groove defined in the surface of the layer, without being covered by the layer of copper, and the plurality of thermal engravings are spaced apart from each other.

2. The printed circuit board of claim 1, wherein a depth of each thermal engraving is greater than or equal to a thickness of the layer of copper.

3. The printed circuit board of claim 1, wherein each thermal engraving is an arc-shaped groove.

4. The printed circuit board of claim 3, wherein the plurality of thermal engravings is arranged surrounding the through hole, and corresponding ends of every two adjacent thermal engravings are juxtaposed.

5. The printed circuit board of claim 1, wherein the layer is a ground layer.

6. A manufacturing method of a printed circuit board, the printed circuit board defining a through hole passed through the printed circuit board, the manufacturing method comprising:
arranging a layer of copper on a surface of a layer of the printed circuit board; and
defining a plurality of grooves around the through hole separately, wherein the plurality of grooves without being covered by the layer of copper is defined in the layer, and are not in contact with each other.

7. The manufacturing method of claim 6, wherein each groove is arc-shaped.

8. The manufacturing method of claim 6, wherein the layer is a ground layer.
